(19) United States
(12) Patent Application Publication
(10) Pub. No.: US 2001/0036280 A1
(43) Pub. Date: Nov. 1, 2001

(54) Active noise cancellation system recalibration

(76) Inventors: John F. Astorino, Livonia, MI (US); Ian R. McLean, Chatham (CA); Trevor Laack, Oregon, WI (US)

Correspondence Address: LAURA M. SLENZAK, SIEMENS CORPORATION, 186 WOOD AVENUE SOUTH, ISELIN, NJ, 08830, US

(21) Appl. No.: 09/827,794

(22) Filed: Apr. 6, 2001

Related U.S. Application Data
(60) Provisional application No. 60/209,532, filed on Jun. 5, 2000.

(51) Int. Cl. H03B 29/00

(52) U.S. Cl. 381/71.4

(57) ABSTRACT

The method of noise attenuation comprises the steps of generating a noise canceling signal based on an environmental assumption, assessing the environmental assumption of the control unit, and altering the noise canceling signal based on the assessment. Assessing may comprise the step of comparing the environmental assumption with actual environmental data, including the step of generating a test sound wave to obtain actual environmental data. The test sound wave is then compared to a model of the sound wave based on the environmental assumption. This method is embodied in a system that includes an air induction body, a speaker in proximity to the air induction body, a microphone in communication with the speaker, a reference sensor, and a control unit with a noise cancellation feature with an environmental assumption. The control unit is in communication with the speaker, reference sensor, and the microphone and assesses the environmental assumption in light of actual environmental data.

This application claims priority to Provisional Patent Application Serial No. 60/209,532 filed Jun. 5, 2000.

### BACKGROUND OF THE INVENTION

This invention relates to an active method and system for controlling automotive induction noise.

Manufacturers have employed active and passive methods to reduce engine noise within the passenger compartment. Such noise frequently emanates from the engine, travels through the air induction system and emanates out of the mouth of the air intake into the passenger compartment. Efforts have been made to reduce the amount of engine noise traveling through the air induction system. These efforts include the use of both passive devices such as expansion chambers and Helmholtz resonators and active devices involving anti-noise generators.

Active systems use a speaker to create a canceling sound that attenuates engine noise. The sound created is out of phase with the engine noise and combines with this noise to result in its reduction. Generally, this sound is generated in proximity to the mouth of the air induction system. In one such system, a control unit, such as a digital signal processor, obtains data from the vehicle engine, creates a predictive model of engine noise, and thereby generates the appropriate cancellation signal based on the results of this model. This signal is then transmitted to the speaker, which transforms this signal into a canceling sound. Because the control unit may not perfectly model engine noise, an error microphone is placed in proximity to the mouth of the air induction system to determine if engine noise need be further attenuated.

In this system, certain assumptions are made about the ambient environment in the engine noise model. Because these environmental assumptions may differ from environmental conditions actually experienced by the system, the system may inaccurately predict engine noise, consequently resulting in less than optimal noise attenuation. Moreover, under certain low engine load conditions, inaccurate modeling may result in the generation of an undesirable high pitch sound.

One way to resolve this problem is proposed by another invention whereby the noise attenuation feature of the system is disabled under certain conditions. However, simply disabling the system under these circumstances does not resolve the problem with the system that arises from changing environmental conditions. Accordingly, a need therefore exists to prevent the generation of this undesirable tone and improve noise attenuation in light of changing environmental conditions.

### SUMMARY OF THE INVENTION

The invention concerns a method and system for noise attenuation. As known, to attenuate engine noise, a noise canceling signal is generated by a control unit, a computer, that emits this signal through a speaker in proximity to the source of the noise. This noise canceling signal is generated based on an environmental assumption about air temperature, humidity, air pressure, or other environmental condition. In this invention, however, the environmental assumption is assessed and the noise canceling signal is altered based on the assessment.

The assessment may comprise comparing the environmental assumption with actual environmental data. A test sound wave is generated to obtain actual environmental data. Because the test sound wave travels through the actual environment, the test sound wave is affected by the environment. The test sound wave is then compared with a model of a sound wave based on the environmental assumption. Differences between the test sound wave and the model of the sound wave based on the environmental assumption reveal environmental data that may then be used to alter the noise canceling signal. For example, if the test sound wave differs in speed from the model of the sound wave based on the environmental assumption, the noise canceling signal may require alteration.

The environmental assumption may be assessed more than once as well as over a predetermined period of time. Such an assessment may take place while the noise canceling feature is disabled such as when a system condition exists that may lead to the generation of undesirable noise by the noise attenuation system. In this situation, the test sound wave is generated following the disabling of the noise attenuation feature. A comparison of the test sound wave with the model of the sound wave based on the environmental assumption also takes place while the system is disabled. If differences arise between the two sound waves, then the noise canceling signal may be altered.

The foregoing method may be embodied in an air induction system comprising, an air induction body, a speaker in proximity to the air induction body, a microphone in communication with the speaker, a reference sensor, and a control unit with a noise attenuation feature based on an environmental assumption. The control unit communicates with the speaker, the microphone, and reference sensor, assessing the environmental assumption and potentially altering the noise attenuation feature based on the assessment. The control unit may assess the environmental assumption by comparing the environmental assumption with actual environmental data. The speaker may generate a test sound wave to obtain actual environmental data while the microphone receives this test sound wave. The control unit compares the two sound waves in its determination of whether to alter the noise canceling signal.

Accordingly, the invention generates a noise canceling signal from the control unit based on an environmental assumption, assesses the environmental assumption, and alters the noise canceling signal based on the assessment. This process may be repeated at regular or sporadic intervals to permit continual assessment and alteration of the environmental assumptions. To ensure accurate measurement of the environmental condition, the condition may be sensed for a predetermined period of time.

### BRIEF DESCRIPTION OF THE DRAWINGS

The various features and advantages of this invention will become apparent to those skilled in the art from the following detailed description of the currently preferred embodiment. The drawings that accompany the detailed description can be briefly described as follows:

FIG. 1 shows a schematic view of the system employing the embodiment of the invention.

FIG. 2 shows a flowchart of an embodiment of the invention.

### DETAILED DESCRIPTION OF THE PREFERRED EMBODIMENT

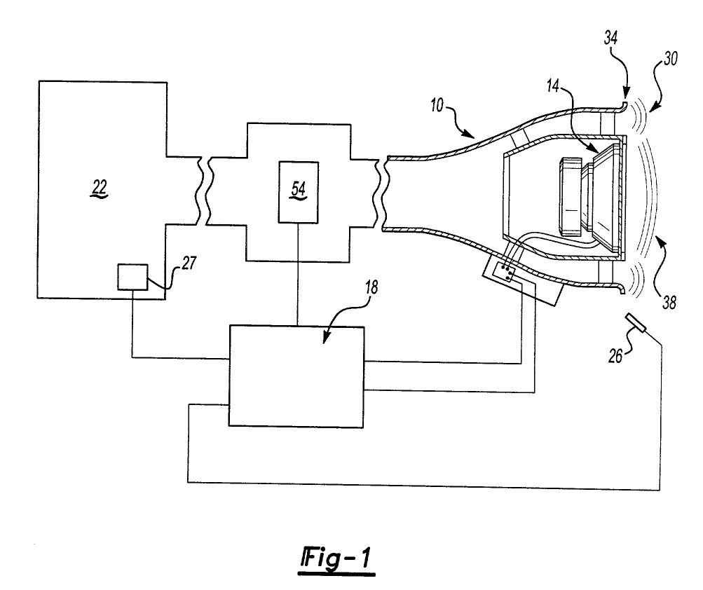

FIG. 1 illustrates the method and system of noise attenuation of an embodiment of the invention. Pictured schematically are air induction body 10 and speaker 14, preferably disposed in air induction body 10, control unit 18, engine 22, microphone 26, and reference sensor 27, such as an engine tachometer. Engine noise 30 from engine 22 travels through air induction body 10 out of mouth 34 of air induction body 10.

Control unit 18 is in communication with speaker 14, microphone 26, and reference sensor 27. As known, reference sensor 27 serves to provide control unit 18 with information on the frequency content of engine noise 30 emanating from mouth 34. During normal operation, control unit 18 has a noise cancellation feature that generates a noise canceling signal 38 through speaker 14. Because noise canceling signal 38 is out of phase with engine noise 30, both noise canceling signal 38 and engine noise 30 are thereby attenuated. Also known in the art, the noise cancellation feature employs a model of engine noise that relies on environmental assumptions about air temperature, air pressure, humidity, and other environmental conditions affecting the communication of sound. Typically, such assumptions are preset.

An embodiment of the invention employs control unit 18 to assess environmental assumptions and to alter the noise attenuation feature based on the assessment. Control unit 18 assesses the environmental assumptions by comparing these assumptions with actual environmental data. Speaker 14 may generate a test sound wave, which is received by microphone 26. Because the test sound wave travels through the actual environment, the test sound wave is affected by the environment and then compared by control unit 18 with a model of a sound wave based on the environmental assumption. Differences between the test sound wave and the model, such as their relative speeds, may reveal differences between the actual environment and the assumed environment. Such environmental data may then be used to recalibrate control unit 18 and thereby alter noise canceling signal 38 to account for the changed environment. A person with ordinary skill in the art can determine other means to obtain actual environmental data used to assess any underlying environmental assumption of the model. The process of assessing by control unit 18 may occur more than once and over a predetermined period of time to ensure both accurate measurements of environmental data without significant burdening of control unit

As more fully disclosed in pending U.S. patent application No. ______ filed on the same day of this application, which is hereby incorporated by reference, the invention may be used in conjunction with the method of noise attenuation whereby noise attenuation is ceased under a certain system condition such as a condition likely to lead to the generation of unwanted noise by the system. In such an embodiment, when a predetermined system condition is detected by microphone 26, the noise cancellation feature of control unit 18 is disabled. Preferably, the predetermined system condition is based on engine noise level received by microphone 26, background noise level received by microphone 26, or a relationship between the level of the engine noise to be attenuated and the level of background noise around the engine compartment. For example, a low engine noise level to background noise level would indicate a situation where unwanted noise may be generated. In this situation as well as other circumstances, control unit 18 disables the noise attenuation feature to prevent the generation of unwanted noise. While the noise attenuation feature is disabled, control unit 18 recalibrates as described above. The disabling of the noise attenuation feature may occur prior to the assessing of the environmental assumption of control unit 18.

Another system condition reviewed by the system is the position of the vehicle throttle. Sensor 54 detects the position of the throttle blade and communicates this position to control unit 18. If microphone 26, detects a high pitch sound while sensor 54 detects the throttle position as moved toward closed, then control unit 18 deduces that the sound is unwanted noise from the system and shuts off its noise attenuation feature, thereby eliminating the high pitch sound while control unit 18 recalibrates.

Once a change is detected in the system condition, control unit 18 may again commence noise attenuation by generating another noise canceling signal based on a model with updated environmental assumptions. Control unit 18 may further record the cessation of the generation of the noise canceling signal based upon the system condition. Control unit 18 may read this cessation as a system error or malfunction. In this way, if the number of errors exceeds a preset level, then control unit 18 deduces a system error and ceases noise attenuation for a predetermined amount of time to permit systems conditions to change to where noise attenuation may proceed without undesirable noise. Control unit 18 may issue an error message to the driver as well. After a predetermined amount of time, the system once again commences noise attenuation. In the event errors persist, then control unit 18 may permanently disable noise attenuation until the system is serviced.

The method of noise attenuation involves generating a noise canceling signal 38 based on an environmental assumption from control unit 18, assessing the environmental assumption of control unit 18, and altering the noise canceling signal 38 based on the assessment. The assessing may comprises comparing the environmental assumption with actual environmental data. The environmental data may be obtained by generating a test sound wave as described above. The test sound wave is then compared to a model of the sound wave based on the environmental assumption. In particular, the characteristics of the sound waves, such as their relative speeds, may be compared to obtain important information about the actual environment. The environmental assumption may be assessed more than once and for a predetermined period of time to ensure accuracy of the modeling.

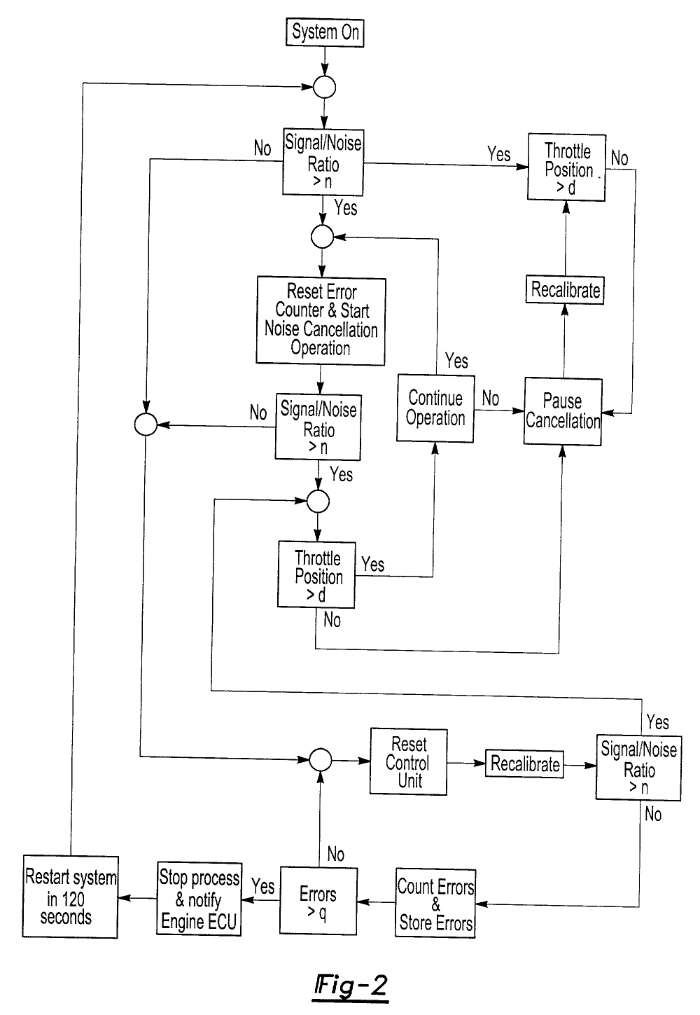

FIG. 2 is a flowchart of an embodiment of the above described method and system. When the system is “on”, control unit 18 checks microphone 26 to determine whether the engine noise 30 to background noise ratio is above a predetermined level (n) to avoid generation of unwanted high pitch noise. If so, then normal operation of noise attenuation takes place and, as explained below, error counter is reset.

Control unit 18 again checks microphone 26 to review the current engine noise 30 to background noise ratio following noise attenuation. If this ratio is greater than n, then control unit 18 checks sensor 54 to determine throttle position. If throttle position is open over a predetermined amount (d) as sensed by a throttle position sensor as known in the art, control unit 18 proceeds to determine whether control unit 18 need continue operation. If yes, then control unit 18 loops back to its noise attenuation routine. If not, then control unit 18 pauses noise attenuation. Attenuation is paused until throttle is once again open as detected. When throttle is moved to open above a predetermined level (d), then control unit 18 loops back to its noise attenuation routine. While noise attenuation is paused, control unit 18 recalibrates based on actual environmental condition as described above.

If control unit 18 determines that the ratio between engine noise 30 and background noise is less than a predetermined level n for normal operation of noise attenuation, then control unit 18 resets to clear any system problem and checks again the ratio of engine noise 30 to background noise. Following reset, control unit recalibrates. If the ratio is high, then control unit 18 checks the throttle position as shown. On the other hand, if the ratio is below a predetermined level n, then the error is counted and recorded. In the event that the number of errors exceeds a preset limit (q) as determined, then control unit 18 stops the noise attenuation process and notifies the engine computer of the error. Control unit 18 restarts, however, after a predetermined time period, in one example 120 seconds, to give the opportunity for the error to clear itself. After this period, control unit 18 recommences the process.

The aforementioned description is exemplary rather then limiting. Many modifications and variations of the present invention are possible in light of the above teachings. The preferred embodiments of this invention have been disclosed. However, one of ordinary skill in the art would recognize that certain modifications would come within the scope of this invention. Hence, within the scope of the appended claims, the invention may be practiced otherwise than as specifically described. For this reason the following claims should be studied to determine the true scope and content of this invention.

What is claimed is:

1. A method of noise attenuation comprising the steps of:
generating a noise canceling signal from a control unit based on an environmental assumption;
assessing the environmental assumption of the control unit; and
altering the noise canceling signal based on the assessment.

2. The method of claim 1 wherein assessing comprises the step of comparing the environmental assumption with actual environmental data.

3. The method of claim 2 further including the step of generating a test sound wave to obtain actual environmental data.

4. The method of claim 3 wherein comparing comprises comparing the test sound wave with a model of the sound wave based on the environmental assumption.

5. The method of claim 4 wherein comparing comprises comparing the speeds of the test sound wave and the model of the sound wave.

6. The method of claim 1 wherein the environmental assumption is assessed more than once.

7. The method of claim 1 wherein assessing occurs for a predetermined period of time.

8. The method of claim 1 further including the step of ceasing the generation of the noise canceling signal based on a system condition.

9. The method of claim 8 wherein the step of ceasing the generation of the noise canceling signal occurs prior to the step of assessing the environmental assumption of the control unit.

10. A method of noise attenuation comprising the steps of:
generating a noise canceling signal from a control unit based on an environmental assumption;
sensing a system condition;
ceasing the generation of the noise canceling signal based on the system condition;
assessing the environmental assumption of the control unit; and
altering the noise canceling signal based on the assessment.

11. The method of claim 10 wherein assessing comprises the step of comparing the environmental assumption with actual environmental data.

12. The method of claim 11 further including the step of generating a test sound wave to obtain actual environmental data.

13. The method of claim 12 wherein comparing comprises comparing the test sound wave with a model of the sound wave based on the environmental assumption.

14. The method of claim 13 wherein comparing comprises comparing the speeds of the test sound wave and the model of the sound wave.

15. The method of claim 10 wherein the environmental assumption is assessed more than once.

16. The method of claim 10 wherein assessing occurs for a predetermined period of time.

17. An air induction system comprising:
an air induction body;
a speaker in proximity to said air induction body;
a microphone in communication with said speaker;
a reference sensor; and
a control unit with a noise attenuation feature based on an environmental assumption, communicating with said speaker, said microphone, and said reference sensor, wherein said control unit assesses said environmental assumption and alters said noise attenuation feature based on the assessment.

18. The air induction system of claim 17 wherein said control unit assesses said environmental assumption by comparing said environmental assumption with actual environmental data.

19. The air induction system of claim 18 wherein said speaker generates a test sound wave to obtain actual environmental data.

20. The air induction system of claim 19 wherein said test sound wave is received by said microphone and compared by said control unit with a model of a sound wave based on said environmental assumption.
